(19) United States
(12) Patent Application Publication
(10) Pub. No.: US 2003/0203123 A1
(43) Pub. Date: Oct. 30, 2003

(54) System and method for metal induced crystallization of polycrystalline thin film transistors

(75) Inventors: Quanyaun Shang, Saratoga, CA (US); Fan Cheung Sze, San Jose, CA (US); Robert I. Greene, Fremont, CA (US); Janine Kardokus, San Jose, CA (US); Beom Soo Park, San Jose, CA (US); Soo Young Choi, Fremont, CA (US); Tae Kyung Won, San Jose, CA (US); Qunhua Wang, San Jose, CA (US); William R. Harshbarger, San Jose, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 10/135,023

(22) Filed: Apr. 26, 2002

(51) Int. Cl. C23C 16/00; H05H 1/24

(52) U.S. Cl. 427/569; 118/719; 427/578

(57) ABSTRACT

A cluster tool for forming a poly-Si layer on a substrate comprises (i) a first chamber for depositing silicon onto the substrate to form an a-Si layer on the substrate, (ii) a second chamber for depositing onto the a-Si layer a metal that is capable of inducing nucleation sites in a-Si, and (iii) a third chamber for annealing the α-Si layer, thereby forming the poly-Si layer on the substrate. In one embodiment, the second chamber is a plasma enhanced chemical vapor deposition (PECVD) reactor that includes an upper electrode. An outer surface of the upper electrode is made of a metal that is capable of inducing the nucleation sites. In this embodiment, the metal is deposited onto the substrate from the upper electrode when a plasma is generated between the upper electrode and a lower electrode in the PECVD reactor, thereby causing deposition of the metal onto the substrate.

The present invention generally relates to a system and method for depositing an amorphous silicon layer as well as underlying layers on a substrate, depositing a metal that is capable of inducing nucleation sites in amorphous silicon on the substrate, and crystallizing the treated substrate in a cluster tool. The invention has application in the manufacture of devices such as thin film transistors on insulative substrates, leading to improved manufacturing efficiency.

### BACKGROUND OF THE INVENTION

Polycrystalline (poly-Si) thin films are used in a number of different devices, including infra-red filters, absorbers in solar cells, active mechanical parts in microelectromechanical systems, channel layers in transistors, and active layers in sensor structures. In many such devices, the poly-Si thin film provides improved carrier mobility and stability over an amorphous silicon (a-Si) thin film. In these devices, the poly-Si is a thin film having a thickness that ranges from tens of nanometers (nm) to micrometers (μm).

In one application, poly-Si based thin film transistors are used in modern flat panel displays. Flat panel displays have large liquid crystal cells. The liquid crystal cells contain a liquid crystal material that is sandwiched between two plates. At least one of the plates is transparent and at least one of the plates is made of an insulative substrate such as glass. Thin film transistors (TFTs) are positioned on at least one of the insulative substrate plates in order to separately address different areas of the liquid crystal cell at very fast rates to control the optical characteristics of these areas. The individual areas are called picture elements or pixels. The channel layer in such TFTs is made of a poly-Si film.

It is desirable to provide flat panel displays that are both large and have high resolution. Because of this, it is necessary to address a very large number of pixels within the liquid crystal cell. In modern display panels, more than 1,000,000 pixels are normally present and the same number of TFTs must therefore be formed on the insulative substrate plates so that each pixel is separately addressable. Such TFTs are made by forming a layer of a-Si on the insulative substrate and then annealing the layer of a-Si to form a corresponding poly-Si layer. The poly-Si layer serves as the TFT active region in the TFTs used to address each pixel in a flat panel display.

The annealing step used to crystallize the a-Si film, so that it forms a poly-Si film, requires an annealing phase in which substrate is exposed to a high temperature for a period of time. The duration of the annealing phase is a function of the temperature used. Generally, higher temperatures (above 600° C.) result in short annealing times. Shorter annealing times are highly desirable because the profitable manufacture of liquid crystal displays requires the maximum possible manufacturing throughput. That is, the shorter the annealing step, the more liquid crystal displays can be manufactured in a given period of time using specified production equipment, leading to lower device cost and increased profitability.

Unfortunately, higher annealing temperatures (above 600° C.) have the drawback that such temperatures can deform some types of glass substrates during the anneal. Thus, higher annealing temperatures have proven to be unsatisfactory in practice. Although lower temperatures (below 600° C.) prevent deformation of the glass substrate, such temperatures are unsatisfactory because they dramatically lengthen the annealing times required to crystallize the a-Si film into a corresponding poly-Si film. Such increased annealing times leads to lowered production efficiency and increased production costs.

In the art, it has been discovered that a metal such as nickel, chromium, platinum or palladium, may be used to create nucleation sites on an a-Si layer. Such metals, are termed “nucleating metals” because of their ability to nucleate a-Si crystallization during the anneal stage. See U.S. Pat. No. 6,097,037 (Joo et al. a) and U.S. Pat. No. 6,197,623 (Joo et al. b). The technique of using nucleating metals to facilitate crystallization of an a-Si layer is known as metal-induced crystallization (MIC). Using MIC, an a-Si layer that has been nucleated with a nucleating metal is annealed to form the corresponding poly-Si layer using temperatures in the range of about 350° C. to about 600° C. MIC has the advantage that the poly-Si film is formed on the insulative substrate in shortened anneal times using lower temperatures that do not damage the substrate.

FIGS. 1A to 1C show a method of fabricating a TFT using MIC in accordance with U.S. Pat. No. 6,097,037 (Joo et al. a). Referring to FIG. 1A, an a-Si layer 21 is deposited on insulating substrate 38 and then the a-Si layer is optionally patterned using known techniques such as photolithography and etching to define the dimensions of the active region of each TFT on substrate 38. A gate insulation layer 22 and a gate electrode 23 are then formed on the active layer by conventional processes. Gate insulation layer 22 is made of an insulating material such as SiO₂ or SiN. In FIG. 1B, a nickel layer 24 (thick line) is formed to a thickness of 20 Å or greater by sputtering nickel on the entire surface of the formed structure. Then, a source region 21S and a drain region 21D are formed at portions of the active layer 21 by doping the entire surface of the formed structure with impurities. Between the source and drain regions 21S and 21D, a channel region 21C is formed on the substrate 38.

Referring to FIG. 1C, amorphous silicon in active layer 21 is crystallized by heating substrate 38 to a temperature in the range of about 350° C.-600° C. During the anneal, source and drain regions 21S and 21D, which are directly exposed to nickel layer 24, are crystallized by the process of metal-induced crystallization (MIC). Channel region 21C is crystallized by a process known as metal induced lateral crystallization (MILC). That is, regions 21S and 21D serve as the source of poly-nucleation of active region 21C. Thus, region 21C is crystallized in a lateral fashion, with nucleation beginning at the 21S/21C and 21D/21C interface and extending inward, until the entire region 21C is crystallized. Impurities are activated in the source and drain regions 21S and 21D during the annealing phase as the a-Si is crystallized into poly-Si in active layer 21.

The method summarized in FIG. 1 is not satisfactory, however, because the boundaries between regions of layer 21 that are crystallized by MIC (21S and 21D) and the region that is crystallized by MILC (21C) are located at the junctions 54 where the source or drain region meets the channel region of the TFT. Because of this, there is an abrupt difference in the crystal structure at junctions 54. Furthermore, the nucleating metal from the MIC regions 21S and 21D contaminates the adjacent MILC region. Consequently, a trap is formed at such junctions as soon as the TFT is turned on. This trap causes unstable channel regions and deteriorates the characteristics of the TFT.

Some of these problems with the process described in FIG. 1 have been addressed by work presented in references such as U.S. Pat. No. 6,097,037 (Joo et al.) and Lee & Joo, IEEE Electron Device Letters, 17, 160-162, 1996. In this work, nucleating metal layer 24 is offset away from the portion of regions 21S and 21D that abut region 21C. Because of this offset, nucleating metal layer 24 is limited to regions 28A and 28B (FIG. 1A) on substrate 38. A number of conventional techniques may be used to create a nucleating metal layer 24 that has such an offset. In one such method, a photoresist is applied to the structure illustrated in FIG. 1A. Then, the photoresist layer is patterned such that it has an offset that is about 0.02 μm longer than the gate electrode length by patterning photoresist PR with a photo process. Nucleating metal layer 24 is then applied as described above to the substrate 38 that includes this patterned photoresist layer. The photoresist pattern is removed, leaving a nucleating metal layer 24 that is offset from gate 56 and limited to regions 28A and 28B. Thus, upon annealing, the junctions 54 between MIC and MILC regions of layer 21 are offset from gate region 21C. Because of the offset, gate region 21C exposure to nucleating metal is reduced. This is advantageous because significant contamination of gate region 21C with a nucleating metal could destabilize the electrical characteristics of the TFT.

The efficient manufacture of flat panel displays is greatly facilitated by the use of highly integrated production equipment, known as a cluster tool, in which each of the modules or chambers used to process the glass substrate is connected to a central transfer chamber. For example, a cluster tool used to manufacture liquid crystal displays includes a plasma enhanced chemical vapor deposition (PECVD) chamber for depositing a-Si layer 21 (FIG. 1A) onto insulative substrate 38. Such production equipment is available from Applied Materials, Inc., Santa Clara, Calif.

One disadvantage of known MIC techniques is that they require the use of many types of systems that are not readily adaptable to a cluster tool environment. Thus, the efficiency of conventional techniques for MIC and/or MILC-BASED TFT manufacture is not satisfactory because such processes are not automated and require several time-consuming manual transfers of substrates between the several different systems that are needed in order to manufacture the TFTs. For example, the sputtering process used to deliver nucleating metal layer 24 (FIG. 1B) cannot readily be incorporated into a cluster tool because the sputterer has vacuum characteristics that differ significantly from those of the insulative substrate cluster tool. A sputtering module operates with a vacuum of about 10⁻⁹ Torr whereas a cluster tool for processing insulative substrates operates with a vacuum of about 10⁻³ Torr. Incorporation of the sputterer into the cluster tool would require the development of load-lock chambers that would significantly increase the complexity of the cluster tool and significantly slow down the entire flat panel display production process. Because the sputterer is not readily adaptable to the cluster tool, substrates 38 must be removed from the cluster tool and placed in a sputterer in order to layer the substrate with nucleating metal. This transfer is time-consuming and exposes the substrate to atmosphere at an early stage in the TFT manufacturing process. As a second example of the inefficiency of prior art processes, the photo process used to pattern the photoresist layer that is used to offset the nucleating metal layer 24 in accordance with the techniques of Joo et al. a is not readily adaptable to the cluster tool environment.

In addition to reduced efficiency, the need for multiple systems in prior art processes has additional disadvantages. Usage of multiple systems increases the overall footprint of the substrate processing equipment, thereby increasing production costs. Furthermore, the use of several systems necessitates several manual transfers, exposes the substrates to potentially contaminating atmosphere, and leads to cross contamination of the various systems used to process the substrate.

In summary, known techniques for manufacturing TFTs on insulative substrates are not satisfactory. Although techniques such as MIC have decreased the a-Si to poly-Si anneal times, MIC has necessitated a cumbersome multisystem manufacturing environment in which a number of manual transfers are required. Given the above background, what is needed in the art are more efficient systems and methods for coating a substrate with a nucleating metal. In particular, what is needed in the art are systems and methods for exposing an insulative substrate with a metal capable of inducing nucleation sites without first removing the substrate from the cluster tool environment.

### SUMMARY OF THE INVENTION

The present invention provides a system and method for coating an a-Si layer with a metal that is capable of inducing nucleation sites (nucleating metal) in the a-Si layer in a cluster tool environment. In one embodiment, the nucleating metal is deposited on the glass substrate before the a-Si and an insulative layer are deposited onto the substrate. In another embodiment, the nucleating metal is deposited onto the substrate after the a-Si has been deposited onto the substrate.

In the present invention, the nucleating metal is deposited using a plasma-enhanced chemical vapor deposition chamber (PECVD) reactor in which an outer surface of the upper electrode in the PECVD reactor is made of the nucleating metal. When the upper electrode of the PECVD reactor is energized, the nucleating metal disassociates from the upper electrode and coats the substrate. A PECVD reactor has vacuum characteristics that are similar to other modules found in cluster tools designed to process insulative substrates. Therefore, the PECVD reactor of the present invention is advantageous because it can be incorporated as a module into cluster tools that processes insulative substrates.

One aspect of the present invention provides a PECVD reactor for depositing a metal (nucleating metal) onto a substrate. The nucleating metal is capable of inducing nucleation sites in amorphous silicon (a-Si). The PECVD reactor includes a deposition chamber. There is an upper electrode and a lower electrode in the deposition chamber. An outer surface of the upper electrode is made of the nucleating metal. The lower electrode is a susceptor that holds a substrate. When the lower electrode is at a potential that is sufficiently different from that of the upper electrode, a plasma between the upper electrode and the lower electrode is generated. Further, the metal is sputtered from the upper electrode onto the substrate causing deposition of the metal onto the substrate.

In various embodiments of the present invention, the nucleating metal used to form the outer surface of the upper electrode is iron, cobalt, rubidium, palladium, osmium, iridium, platinum, scandium, titanium, vanadium, chromium, manganese, copper, zinc, gold, silver or alloys or combinations thereof. In one embodiment of the invention, the nucleating metal is nickel or palladium. In another embodiment, the upper electrode is a gas inlet manifold and the lower electrode is a substrate electrode.

Another aspect of the invention provides a method for forming a poly-Si layer on a substrate using a cluster tool that includes the aforementioned specialized PECVD reactor as well as a standard PECVD reactor. In the method, the substrate is introduced into the specialized PECVD reactor. The specialized PECVD reactor includes an upper electrode and a lower electrode. An outer surface of the upper electrode is made of a nucleating metal. A plasma is generated between the upper electrode and the lower electrode, thereby causing the nucleating metal to sputter onto the substrate from the upper electrode. The substrate is transferred to the standard PECVD chamber and a-Si is deposited onto the substrate to form an a-Si layer. Then, the substrate is transferred to a heat chamber in order to thermally anneal the substrate, thereby forming the poly-Si on the substrate by crystallization of the a-Si layer.

Yet another aspect of the present invention provides a method for forming a poly-Si layer on a substrate using a cluster tool that includes a specialized PECVD reactor and a conventional PECVD reactor. In the method, an a-Si layer is deposited onto the substrate using the conventional PECVD reactor chamber to form an a-Si layer. The substrate is then introduced into the specialized PECVD reactor. The specialized PECVD reactor includes an upper electrode and a lower electrode. The upper electrode has an outer surface made of a nucleating metal. A plasma is generated between the upper electrode and the lower electrode, thereby causing the nucleating metal to sputter onto the a-Si layer from the upper electrode. Finally, the substrate is transferred to a heat chamber in order to thermally anneal the a-Si layer, thereby forming the corresponding poly-Si layer on the substrate.

### BRIEF DESCRIPTION OF THE DRAWINGS

Additional objects and features of the invention will be more readily apparent from the following detailed description and appended claims when taken in conjunction with the drawings, in which:

FIGS. 1A through 1C illustrate a method of fabrication a thin film transistor in accordance with known art.

FIG. 2 is a schematic sectional view of a plasma-enhanced chemical vapor deposition chamber in accordance with one embodiment of the present invention.

FIG. 3 is a cluster tool for processing insulative substrates in accordance with one embodiment of the present invention.

FIGS. 4A and 4B respectively illustrate layers that are deposited onto insulative substrates in accordance with two embodiments of the present invention.

### DESCRIPTION OF THE PREFERRED EMBODIMENTS

The present invention provides a cluster tool system that has a specialized PECVD module that is capable of depositing a metal catalyst such as nickel, chromium, platinum or palladium onto a substrate in order to facilitate metal induced crystallization of an a-Si layer deposited on the substrate. The cluster tool system is advantageous because it supports both the process of a-Si deposition and the process of metal catalyst deposition in a single cluster tool environment. In a typical processing sequence supported on the cluster tool of the present invention, a glass substrate is preheated. Then, as disclosed in more detail below, layers of SiN, SiO₂, and a-Si are deposited on the substrate using conventional deposition techniques. After the deposition of these layers in one or more conventional deposition modules integrated into the cluster tool, the substrate is transferred to a specialized PECVD chamber where a nucleating metal is deposited onto the substrate. Metal-induced crystallization of the a-Si is then performed in a heating chamber. In some embodiments, this heating chamber is the same heating chamber used to perform the preheat or is some other heating chamber attached to the cluster tool. Such embodiments are advantageous because the entire metal-induced crystallization process is performed without any requirement that the substrate leave the cluster tool environment.

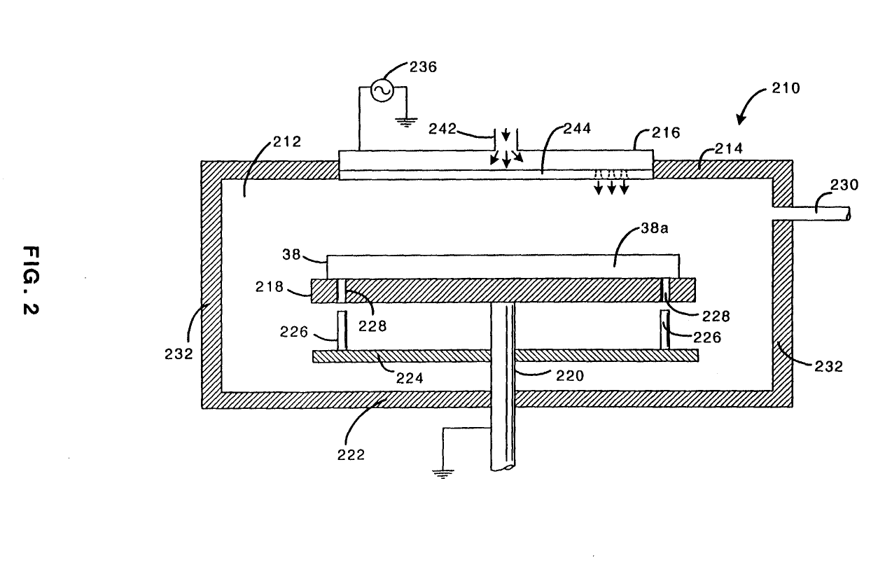

Referring to FIG. 2, there is shown a sectional view of a specialized PECVD reactor 210 in accordance with one embodiment of the present invention. The PECVD reactor of the instant invention is designed to coat a metal that is capable of inducing nucleation sites in an a-Si layer. PECVD reactor 210 includes a deposition chamber 212 that includes an upper electrode 216 and a lower electrode 218. An outer surface of the upper electrode 216 is made of the metal that is capable of inducing nucleation sites in a-Si (nucleating metal). Lower electrode 218 is a susceptor for holding a substrate 38. When lower electrode 218 is held at a potential different from that of the upper electrode 216, a plasma between the upper electrode and the lower electrode is generated. Because of interactions between the plasma and the outer surface of upper electrode 216, the nucleating metal is sputtered from the upper electrode onto substrate 38, thereby causing the deposition of a layer of nucleating metal onto substrate 38.

In conventional PECVD reactors, the upper electrode is a gas inlet valve (also known as a shower head) that is typically made of a material such as 6061 aluminum alloy. In some conventional PECVD reactors, the upper electrode is made of aluminum that has been anodized by dipping the electrode in sulfuric acid, thereby forming a layer of aluminum oxide (Al₂O₃) over the surface of the upper electrode. In yet other conventional PECVD reactors, the upper electrode is made of aluminum that has been coated with a thin coat of aluminum flouride (AlF₃) or other fluorine-based compound. During operation of conventional PECVD reactors, the upper electrode reacts with the plasma generated in the chamber. As a result of such undesirable reactions, metal residues and byproducts coat the inner surfaces of the chamber as well as the substrate after operation of the PECVD reactor. Typically, the metal residues and byproducts are physically wiped off the internal surfaces of the chamber on a periodic basis. For example, when an NF₃ plasma is generated in a conventional PECVD reactor having an upper electrode made of aluminum, the NF₃ plasma reacts with the aluminum upper electrode to generate a certain amount of AlₓF_{y} which subsequently coats both the substrate and interior surfaces within the PECVD reactor. The AlₓF_{y} is periodically wiped off the interior surfaces.

In the PECVD reactor of the present invention, an outer surface of the upper electrode is made of a nucleating metal that is capable of inducing nucleation sites in a-Si. Metals that are capable of inducing nucleation sites in a-Si include iron, cobalt, rubidium, palladium, osmium, iridium, platinum, scandium, titanium, vanadium, chromium, manganese, copper, zinc, gold, silver or combinations or alloys thereof. Then, when a plasma is generated between the upper and lower electrodes, residues and/or byproducts that include the nucleating metal are coated onto substrate 38.

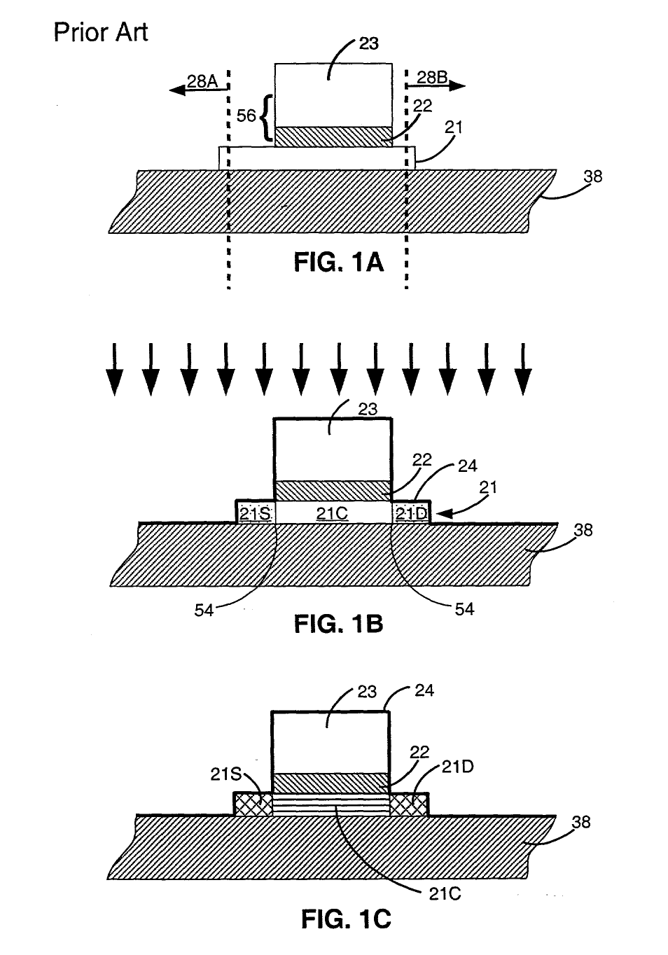

A significant advantage of the present invention is the amount of nucleating metal that is coated onto substrate 38. While prior art techniques describe a nucleating metal layer 24 (FIG. 1) that has a thickness of 20 Å or more, in one embodiment of the present invention, a layer of nucleating metal having a thickness of less than 10 Å is deposited onto substrate 38. In fact, in one embodiment of the present invention, the layer of nucleating metal that is deposited onto substrate 38 is not a contiguous layer. Rather, isolated islands of nucleating metal are applied to substrate 38. It has been determined that, while the layer of nucleating metal that is exposed to the a-Si layer may be thicker than 10 Å, isolated islands of nucleating metal are sufficient to provide the desired crystallization of a-Si into poly-Si at reduced annealing temperatures. In fact, because reduced quantities of nucleated metal are applied to substrate 38, no special care needs to be taken to prevent exposure of region 21C (FIG. 1B) to nucleating metal. Thus, there is no requirement in the instant invention to use laborious manual techniques to offset MIC/MILC boundaries 54 (FIG. 1B) from the gate region of the TFT.

PECVD reactor 210 (FIG. 2) is further advantageous because it can be incorporated into the same cluster tool that is used to deposit the a-Si layer onto substrate 38. Thus, using PECVD 210, the nucleating metal can be deposited onto insulative substrates without removing the substrate from the cluster tool. Furthermore, the metal-induced crystallization can be performed in the same cluster tool by transferring substrate 38 into a heat chamber that is attached to the cluster tool after the nucleating metal has been deposited onto substrate 38 by PECVD reactor 210.

Now that an overview of certain novel aspects of the present invention has been described, a more detailed description of the PECVD reactor of the instant invention is disclosed. As described above, apparatus 210 (FIG. 2) comprises a deposition chamber 212 that has an opening across a top wall 214 as well as a first electrode 216 within the opening. In some embodiments of the present invention, the first electrode 216 is a gas inlet manifold 216, which is also known in the art as a shower head. Alternatively, top wall 214 is solid and electrode 216 is adjacent to the inner surface of top wall 214. Within chamber 212 there is a susceptor 218 in the form of a plate that extends parallel to the first electrode 216. Susceptor 218 is typically made of aluminum and coated with a layer of aluminum oxide. Susceptor 218 is connected to ground or some potential other than that applied to electrode 216 so that it serves as a second electrode. Susceptor 218 is mounted on the end of a shaft 220 that extends vertically through a bottom wall 222 of deposition chamber 212. Shaft 220 is movable vertically so as to permit the movement of susceptor 218 vertically toward and away from electrode 216.

A lift-off plate 224 extends horizontally between susceptor 218 and bottom wall 222 of deposition chamber 212 substantially parallel to susceptor 218. Lift-off pins 226 project vertically upwardly from lift-off plate 224. The lift-off pins 226 are positioned to be able to extend through holes 228 in susceptor 218, and are of a length slightly longer than the thickness of the susceptor 218. While there are only two lift-off pins 226 shown in the figure, there may be more lift-off pins 226 spaced around the lift-off plate 224.

A gas outlet 230 extends through a side wall 232 of deposition chamber 212. Gas outlet 230 is connected to means (not shown) for evacuating the deposition chamber 212. A gas inlet pipe 242 extends through the first electrode or the gas inlet manifold 216 of the deposition chamber 212, and is connected through a gas switching network (not shown) to sources (not shown) of various gases. Electrode 216 is connected to a power source 236. Power source 236 is typically a RF power source. A transfer plate (not shown) is typically provided to carry substrates through a load-lock door (not shown) into deposition chamber 212 and onto the susceptor 218, and also to remove the coated substrate from the deposition chamber 212.

In operation of PECVD reactor 210, a substrate 38 is first loaded into deposition chamber 212 and is placed on susceptor 218 by the transfer plate (not shown). Substrate 38 is of a size to extend over the holes 228 in the susceptor 218. One size of glass used for thin film transistor substrates 38 is approximately 360 mm by 464 mm. However, unlike semiconductor manufacturing arts, the insulative substrate industry has not standardized on specific insulative substrate sizes. Accordingly, insulative substrates processed by deposition apparatus may in fact be any size, such as 550 mm by 650 mm, 650 mm by 830 mm, 1000 mm by 1200 mm or larger. In one embodiment, substrate 38 is made of glass. In less preferred embodiments, substrate 38 is made of quartz. It will be appreciated that the principles of the present invention are not limited by substrate size and that the invention is applicable to the processing of insulative substrates of any size. However, care must be taken to make sure that the upper electrode is the same size as, or slightly larger than, that portion of substrate 38 that includes TFTs. Typically, the entire surface area of substrate 38 is utilized to manufacture TFTs. Accordingly, in typical embodiments, upper electrode 244 has the same, or slightly larger dimensions, as substrate 38 so that substrate 38 is uniformly exposed to nucleating metal and/or byproducts of the nucleating metal.

Susceptor 218 lifts substrate 38 off the lift-off pins 226 by moving shaft 220 upwards such that the lift-off pins 226 do not extend through the holes 228, and the susceptor 218 and substrate 38 are relatively close to the first electrode 216. The electrode spacing or the distance between the substrate surface and the discharge surface of the upper electrode 216 is between about 0.5 to about 2 inches. A more preferred electrode spacing is between about 0.8 to about 1.4 inches.

The nature of the process parameters used to operate PECVD reactor 210 depends upon the exact nucleating metal used to form the outer surface of upper electrode 216, the size of substrate 38, the type of gas used to form a plasma within chamber 212, as well as other variables. Because of this, ranges of process parameters are provided below rather than exact values. Simple experimentation may be performed, for any given process configuration, in order to optimize to specific values within the ranges provided herein.

At the start of the deposition process, deposition chamber 212 is first evacuated through gas outlet 230 such that the pressure within chamber 212 is set to a range of about 0.05 Torr to about 3 Torr. Substrate 38 is positioned on susceptor 218 inside deposition chamber 212 and the temperature of susceptor 218 is raised to a temperature in the range of about 250° C. to about 450° C. Then, a gas is introduced into chamber 212 through gas inlet pipe 242. The type of gas that is introduced into chamber 212 is application dependent. In some embodiments, the gas introduced into chamber 212 is an inert gas such as argon, helium, krypton, or xeon. In other embodiments, the gas introduced into chamber 212 is a reducing gas such as H₂. In yet other embodiments, the gas introduced into the chamber is argon, nitrogen, hydrogen, or mixtures thereof. The flow rate of the gas introduced into chamber 212 through gas inlet pipe 242 is dependent upon the physics involved, but is generally introduced at flow rates of about 100 to about 3000 standard cubic centimeters per minute (sccm). Generally, the flow rate is determined by the size of substrate 38. That is, larger substrate sizes require higher gas flow rates.

Once the temperature, air pressure, and gas flow rates of susceptor 218 have all stabilized to desired ranges or values, radio frequency power is applied to upper electrode 216. Generally, anywhere from 0.2 watts/cm² to about two watts/cm² of radio frequency (RF) power is applied to upper electrode 216. In one embodiment, 0.5 watts/cm² of RF power is applied to upper electrode 216. It will be appreciated that one important way in which to control the amount of nucleating metal that is deposited onto the substrate is to control the plasma power. Specifically, lower plasma power will result in the deposition of less nucleating metal onto the substrate than higher plasma power.

Application of RF power to electrode 216 results in the formation of a plasma from the gas that has been introduced into chamber 212. This plasma interacts with the outer surface of the upper electrode to form nucleating metal byproducts and/or residues. The nucleating metal byproduct and/or residues settle onto substrate 38 to form a thin coat of nucleating metal on substrate 38. In one embodiment, the thin coat of nucleating metal is discontinuous and is characterized by isolated islands or clumps of nucleating metal on substrate 38.

The length of time that the RF power is applied to upper electrode 216 is application dependent. Generally, however, the RF power is applied for a period of time that ranges from about 10 seconds to about five minutes. It will be appreciated that, in addition to the amount of plasma power that is applied, the length of time that the RF power is applied affects the amount of nucleating metal that is deposited on the substrate. Accordingly, longer periods of RF power application will result in larger amounts of nucleating metal deposition than shorter periods of RF power application.

An important feature of the present invention is that the nucleating metal may be dispersed onto substrate 38 either before or after the a-Si layer is deposited onto the substrate. For example, substrate 38 may be introduced into the PECVD reactor of the instant invention before an a-Si layer has been deposited on the substrate. In such instances, the PECVD reactor is used to apply a thin coat of nucleating metal onto substrate 38 and then substrate 38 is transferred to a conventional PECVD reactor where the a-Si layer is deposited over the thin coat of nucleating metal. Embodiments in which the nucleating metal is deposited below the a-Si layer are effective at facilitating metal induced crystallization of the a-Si layer into the corresponding poly-Si layer because the nucleating metal is in direct contact with the a-Si layer. However, it is expected that embodiments in which the a-Si layer is deposited onto substrate 38 before the nucleating metal is deposited are advantageous because less processing and transferring steps are required. This advantage can be seen by reviewing the number of transferring steps required to deposit nucleating metal below the a-Si layer versus the number of transferring steps required to deposit nucleating metal above the a-Si layer.

In the case where nucleating metal is deposited below the a-Si layer, the insulative substrate is first prepped with SiN and SiO₂ layers in a standard deposition chamber. Then, the substrate is transferred to the specialized PECVD chamber where the nucleating metal is deposited. After this, the substrate is transferred back to the standard deposition chamber where the a-Si is deposited. In the alternative embodiment, where the nucleating metal is deposited above the a-Si layer, the SiN, SiO₂, and a-Si layers are all deposited in the standard deposition chamber before transferring the insulative substrate to the specialized PECVD chamber where the nucleating metal is deposited. Thus, for reasons of efficiency, a-Si layer is typically deposited onto substrate 38 using a conventional PECVD reactor before transferring substrate 38 to PECVD reactor 210. Then, PECVD reactor 210 is used to coat the a-Si layer with the nucleating metal prior to metal induced annealing in a heat chamber.

As has been noted above, PECVD reactor 210 is further advantageous because it can be incorporated as a module into a cluster tool that is designed to process insulative substrates. It is important that each module in a cluster tool have compatible vacuum characteristics. Conventional sputterers used to apply a nucleating metal in accordance with known techniques for metal induced a-Si crystallization have vacuum characteristics that are incompatible with cluster tools designed for processing insulative substrates. Such sputterers typically operate at a vacuum of about 10⁻⁹ Torr whereas insulative substrate processing cluster tools operate at a range of about 50 mTorr to about 500 mTorr. The incorporation of a conventional sputterer into such a cluster tool would require the use of specialized load/lock chambers that would increase the complexity and cost of the cluster tool as well as slow down the efficiency of existing TFT manufacturing process. Advantageously, PECVD reactor 210 has vacuum characteristics that are compatible with existing cluster tools. For example, PECVD reactor 210 may be operated at a pressure in the range of about 0.2 Torr to about 3 Torr. The pressure differential between the cluster tool and the operating pressure of PECVD reactor 210 is supported by existing cluster tools without any requirement for specialized load/lock chambers. Thus, PECVD 210 represents a significant advance in the development of a cluster tool environment. In this environment, the entire metal-induced crystallization process is performed in an efficient automated regimen without any need to expose substrates to air during the entire processing regimen.

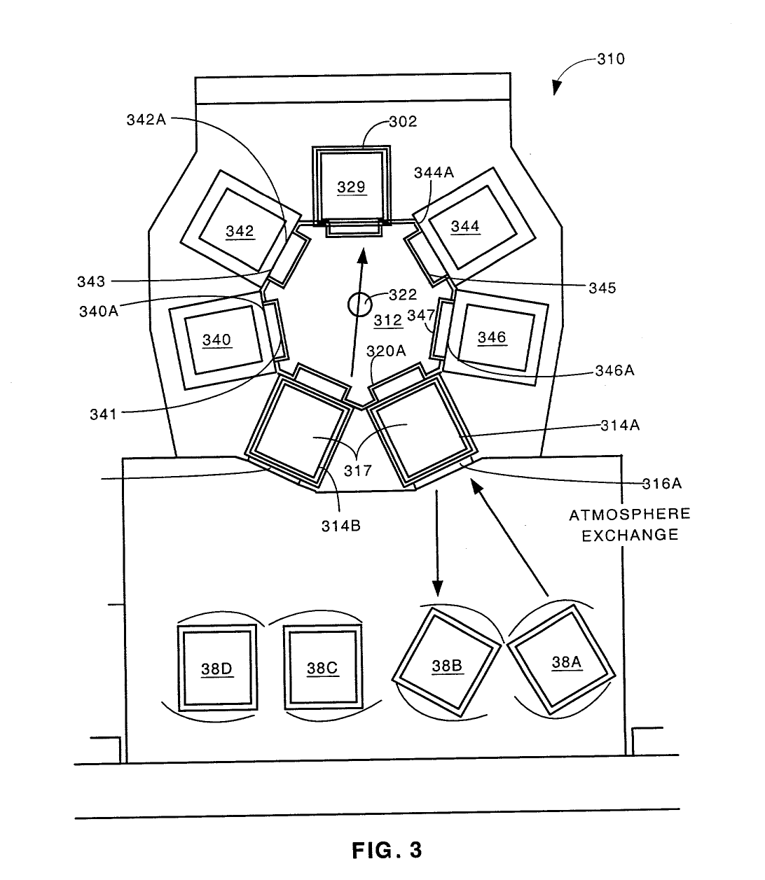

FIG. 3 illustrates a representative cluster tool 310 that incorporates PECVD reactor 210. Thus, cluster tool 310 represents a cluster tool that can be used to process substrates 38 using the metal-induced nucleation process in a highly efficient manner and without exposing substrate 38 to air. Tool 310 comprises a central transfer chamber 312 to which are connected load lock/cooling chambers 314A and 314B, each for transferring substrates 38 into system 310, heating chamber 302, and processing chambers 340, 342, 344, and 346. Central transfer chamber 312, loadlock/cooling chambers 314A and 314B, heating chamber 302, and processing chambers 340, 342, 344, and 346 are sealed together for a closed environment in which the system is operated at internal pressures of about 50 mTorr to about 200 mTorr. Load lock/cooling chambers 314A and 314B have closable openings comprising load doors 316A and 316B, respectively, on their outside walls for transfer of substrates 38 into system 310.

Load lock/cooling chambers 314A and 314B each contain a cassette 317 fitted with a plurality of shelves for supporting and cooling substrates. Cassettes 317 in load lock/cooling chambers 314 are mounted on an elevator assembly (not shown) to raise and lower the cassettes 317 incrementally by the height of one shelf. To load chamber 314A, load door 316A is opened and a substrate 38 is placed on a shelf in cassette 317 from chamber 374. The elevator assembly then raises cassette 317 by the height of one shelf so that an empty shelf is opposite load door 316A. Another substrate is placed on that shelf and the process is repeated until all of the shelves of cassette 317 are filled. At that point, load door 316A is closed and chamber 314A is evacuated to the pressure in system 310.

A slit valve 320A on the inside wall of load lock/cooling chamber 314A adjacent to central transfer chamber 312 is then opened. Substrates 38 are transferred by means of robot 322 in central transfer chamber 312 to a heating chamber 302 where they are preheated to the temperature required for processing operations described below. Robot 322 is controlled by a microprocessor control system (not shown). Robot 322 is used to withdraw a substrate from cassette 317 of load lock/cooling chamber 314A, insert the substrate onto an empty shelf in heating chamber cassette 329 and withdraw, leaving the substrate on a shelf within heating chamber 302. Typically, heating chamber cassette 329 is mounted on an elevator assembly within heating chamber 302. After loading one shelf, heating chamber cassette 329 is raised or lowered to present another empty shelf for access by robot 322. Robot 322 then retrieves another substrate from cassette 317 of load lock/cooling chamber 314A.

In like manner, robot 322 transfers all or a portion of substrates 38 from heating chamber cassette 29 to one of four modules 340, 342, 344 and 346. Each module 340, 342, 344 and 346 is optionally fitted on its inner walls 340A, 342A, 344A and 346A, respectively, with a slit valve 341, 343, 345 and 347, respectively, for isolation of process gases.

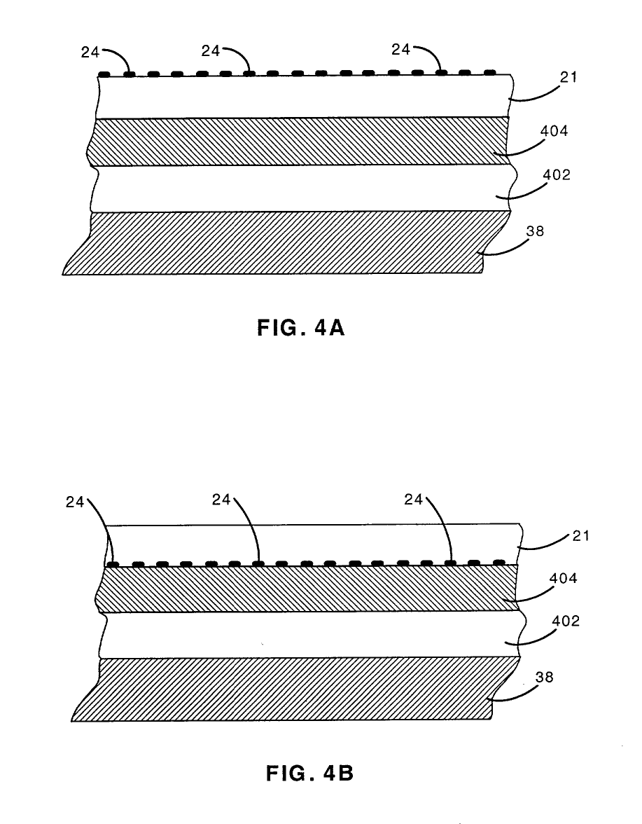

In one embodiment of the present invention, module 342 is a conventional PECVD reactor, and module 340 is a PECVD reactor 210. In this embodiment, an a-Si layer is added to substrate 38 before the nucleating metal is applied to substrate 38. Accordingly, a substrate 38 is preheated in heat chamber 302 to a temperature in the range of about 380° C. to about 430° C. Then, the substrate 38 is transferred to PECVD reactor 342. Reactor 342 is used to place a SiN diffusion layer 402 (FIG. 4A) onto substrate 38. Diffusion layer 402 is typically about 600 Å thick and the plasma reaction time used to deposit layer 402 is on the order of about thirty seconds. After diffusion layer 402 has been deposited, reactor 342 is used to deposit a SiO₂ layer 404 onto SiN layer 402 (FIG. 4A). Typically, the SiO₂ layer 404 is about 1000 to about 2000 Å thick and the plasma reaction time used to create layer 404 in reactor 342 is on the order of about three minutes. After SiO₂ layer 404 formation, PECVD reactor 342 is used to deposit a-Si layer 21 (FIG. 4A) onto SiO₂ layer 404. Generally, a-Si layer 21 is about 400 to about 600 Å thick and the plasma deposition process takes about thirty seconds. After a-Si layer 21 has been deposited, substrate 38 is transferred to PECVD chamber 340 (340 FIG. 3; 210 FIG. 2). Although PECVD chamber 340 (210 FIG. 2) could be used to deposit layers 402, 404, and 21, such a process is disadvantageous because the upper reactor would become coated with SiN, SiO₂ and Si, thereby interfering with the nucleating metal deposition process used to deposit nucleating metal coat 24 onto substrate 38.

In PECVD reactor 340 (340 FIG. 3; 210 FIG. 2), substrate 38 is coated with nucleating metal using the processes described in relation to FIG. 2 above, to form nucleating metal coat 24 (FIG. 1B, FIG. 4A). Advantageously, PECVD reactor 340 (210 FIG. 2) is able to deposit a very thin coat 24 of nucleating metal. In fact, in a preferred embodiment, the nucleating coat is not a discrete layer. Rather, isolated islands of nucleating metal are deposited to substrate 38. After nucleating metal coat 24 had been deposited, substrate 38 is optionally pre-annealed in heat chamber 302 to release hydrogen from a-Si layer 21. When this optional step is performed, substrate 38 is transferred from PECVD chamber 340 to heat chamber 302 and the substrate is heated to a temperature of about 600° C. to about 520° C. for a period of about eight minutes to about fifteen minutes.

In one embodiment, substrate 38 is heated in heat chamber 302 for a period of 10 minutes at a temperature in the range of about 450° C. to about 600° C. in order to convert a-Si layer 21 into a corresponding poly-Si layer after substrate 38 has been coated with a nucleating metal coat 24. Heat chamber 302 is typically has a multi-shelf design and can store many substrates. In some instances, heat chamber 302 can store 12 substrates. In other embodiments, even more than 12 substrates may be stored in heat chamber 302. Furthermore, cluster tool 310 may include more than one heat chamber 302 in order to balance the overall throughput of the deposition processing that is conducted in the cluster tool. For instance, one heat chamber 302 may be dedicated to the preheat stage that occurs before SiN deposition, and another heat chamber 302 may be dedicated to the anneal stage that occurs after SiN SiO₂, a-Si, and nucleating metal layers have been deposited onto substrate 38.

After the a-Si layer has been crystallized into the corresponding active poly-Si layer 21, insulating layer 22 and metal layer 23 are deposited onto active layer 21 and patterned using conventional processes to form TFTs on substrate 38 having the structure illustrated in FIG. 1.

FIG. 4B illustrates an alternative embodiment in which the nucleating metal is deposited onto substrate 38 before a-Si layer 21 is depositied. In such embodiments, layers 402 and 404 are deposited onto substrate 38 using the conventional PECVD reactor 342. Then, substrate 38 is transferred to PECVD reactor 340 where a layer 24 of nucleating metal is applied directly onto layer 404. After layer 24 has been applied, substrate 38 is transferred back to PECVD reactor 342 where the a-Si layer 21 is deposited directly onto layer 24. At this stage, the process steps in this embodiment are the same as those described for FIG. 4A.

The present invention is advantageous because it increases manufacturing productivity. Glass substrates are processed in a single cluster tool environment. The need for multiple systems is eliminated. Multiple processes, including the important metal nucleating deposition stage are performed in the same cluster tool. Thus, the present invention is more automated and efficient than prior art techniques. A number of manual steps associated with the sputtering of nucleating metal onto substrates 38 have been eliminated. The present invention provides a fully automated system for applying nucleating metal to substrates 38. Furthermore, significantly less nucleating metal is used, alleviating need for laborious technique designed to prevent the exposure of channel region 21C of layer 21 to nucleating metals. An advantage of the cluster tool of the present invention is that it reduces manufacturing footprint size by reducing the number of systems required to process the insulative substrates. Also, cross contamination between systems is eliminated because conventional systems that are external to the cluster tool, such as a sputter, are not used.

### Alternate Embodiments

While the present invention has been described with reference to a few specific embodiments, the description is illustrative of the invention and is not to be construed as limiting the invention. Various modifications may occur to those skilled in the art without departing from the true spirit and scope of the invention as defined by the appended claims.

In particular, the present invention has been described with reference to a RF-generated parallel plate plasma source in a PECVD apparatus. However, one of skill in the art will appreciate that the methods and apparatus on the present invention may be used in any device in which a plasma is generated. The present invention is adapted to high density, low pressure plasma sources such as electron cyclotron resonance, high density reflected electron, helicon wave, inductively coupled plasma, and transformed coupled plasma. Furthermore, it will be appreciated that cluster tool 310 is merely exemplary and that many other reactor topologies will work in accordance with the present invention. In a particular, layers 402, 404, and 21 may each be applied in a different PECVD reactor that is attached to cluster tool 310. Furthermore, different types of diffuser layers 402 and/or insulator layers 404 may be used as is known in the art. The description of specific diffuser layers 402 and insulator layers 404 was provided merely to illustrate one embodiment of the present invention. Finally, any number of heat chambers 302, PECVD reactors 210, and conventional deposition systems may be attached to cluster tool 310 in order to balance throughput with deposition processing. Thus, a key advantage of this invention is productivity. Multiple processes are handled in the same system.

What is claimed is:

1. A cluster tool for forming a poly-Si layer on a substrate, comprising:
a first chamber for depositing silicon onto said substrate to form an a-Si layer on said substrate;
a second chamber for depositing onto said a-Si layer a metal that is capable of inducing nucleation sites in a-Si; and
a third chamber for annealing the a-Si layer, thereby forming said poly-Si layer on said substrate.

2. The cluster tool of claim 2 wherein said second chamber is a plasma enhanced chemical vapor deposition (PECVD) reactor, the PECVD reactor comprising:
a deposition chamber;
an upper electrode within said deposition chamber, an outer surface of said upper electrode being made of said metal that is capable of inducing said nucleation sites; and
a lower electrode within said deposition chamber, said lower electrode being a susceptor for holding a substrate and said lower electrode being at a potential different from that of said upper electrode; wherein
said metal is deposited onto said substrate from said upper electrode when a plasma is generated between said upper electrode and said lower electrode, thereby causing deposition of said metal onto said substrate.

3. The cluster tool of claim 2 wherein said plasma is generated from an inert gas.

4. The cluster tool of claim 3 wherein said gas is argon, helium krypton, or xeon.

5. The cluster tool of claim 2 wherein said plasma is generated from a reducing gas.

6. The cluster tool of claim 5 wherein said gas is H₂.

7. The cluster tool of claim 2 wherein said plasma is generated from argon, nitrogen, hydrogen, or mixtures thereof.

8. The cluster tool of claim 1 wherein said metal is iron, cobalt, rubidium, palladium, osmium, iridium, platinum, scandium, titanium, vanadium, chromium, manganese, copper, zinc, gold, silver or a combination or an alloy thereof.

9. The cluster tool of claim 1 wherein said metal is nickel, chromium, platinum, or palladium.

10. The cluster tool of claim 1 wherein said metal is nickel or palladium.

11. The cluster tool of claim 1 wherein said substrate is glass or quartz.

12. A plasma enhanced chemical vapor deposition (PECVD) reactor for depositing onto a substrate a metal that is capable of inducing nucleation sites in a-Si, the PECVD reactor comprising:
a deposition chamber;
an upper electrode within said deposition chamber, an outer surface of said upper electrode being made of said metal that is capable of inducing said nucleation sites; and
a lower electrode within said deposition chamber, said lower electrode being a susceptor for holding a substrate and said lower electrode being at a potential different from that of said upper electrode; wherein
said metal is deposited onto said substrate from said upper electrode when a plasma is generated between said upper electrode and said lower electrode, thereby causing deposition of said metal onto said substrate.

13. The PECVD reactor of claim 12 wherein said metal is iron, cobalt, rubidium, palladium, osmium, iridium, platinum, scandium, titanium, vanadium, chromium, manganese, copper, zinc, gold, silver or a combination or an alloy thereof.

14. The PECVD reactor of claim 12 wherein said metal is nickel, chromium, platinum, or palladium.

15. The PECVD reactor of claim 12 wherein said metal is nickel or palladium.

16. The PECVD reactor of claim 12 wherein said plasma is generated from an inert gas.

17. The PECVD reactor of claim 16 wherein said gas is argon, helium krypton, or xeon.

18. The PECVD reactor of claim 12 wherein said plasma is generated from a reducing gas.

19. The PECVD reactor of claim 18 wherein said gas is H₂.

20. The PECVD reactor of claim 12 wherein said plasma is generated from argon, nitrogen, hydrogen, or mixtures thereof.

21. The PECVD reactor of claim 12 wherein said PECVD reactor is integrated into a cluster tool.

22. The PECVD reactor of claim 21 wherein said substrate includes a layer of a-Si that is exposed to said metal when said plasma is generated between said upper electrode and said lower electrode, thereby providing a source of nucleation for said layer of a-Si without removal of said substrate from said cluster tool.

23. The PECVD reactor of claim 12 wherein said upper electrode is a gas inlet manifold and said lower electrode is a substrate electrode.

24. The PECVD reactor of claim 12 wherein said substrate is an insulative substrate.

25. The PECVD reactor of claim 12 wherein said substrate is glass or quartz.

26. A method for forming a poly-Si layer on a substrate using a cluster tool that includes a first PECVD reactor and a second PECVD reactor, the method comprising:
introducing said substrate into said first PECVD reactor, said first PECVD reactor including an upper electrode and a lower electrode, an outer surface of said upper electrode being made of a metal that is capable of inducing nucleation sites in a-Si;
generating a plasma between said upper electrode and said lower electrode, thereby causing deposition of said metal which is capable of inducing nucleation sites onto said substrate; and
transferring said substrate to said second PECVD reactor and depositing a-Si onto said substrate to form an a-Si layer; and
annealing the α-Si layer on said substrate to thereby form said poly-Si layer on said substrate.

27. The method of claim 26 wherein said metal is iron, cobalt, rubidium, palladium, osmium, iridium, platinum, scandium, titanium, vanadium, chromium, manganese, copper, zinc, gold, silver or a combination or an alloy thereof.

28. The method of claim 26 wherein said metal is nickel, chromium, platinum, or palladium.

29. The method of claim 26 wherein said metal is nickel or palladium.

30. The method of claim 26 wherein said substrate is glass and said generating step delivers a layer of said metal onto said substrate that is less than 10 angstroms thick.

31. The method of claim 26 wherein said substrate is glass and said generating step delivers isolated islands of said metal onto said substrate.

32. The method of claim 26 wherein said upper electrode is a gas inlet manifold and said lower electrode is a substrate electrode.

33. The method of claim 26 wherein said substrate is an insulative substrate.

34. The method of claim 26 wherein said substrate is glass or quartz.

35. A method for forming a poly-Si layer on a substrate using a cluster tool that includes a first PECVD reactor and a second PECVD reactor, the method comprising:
in said second PECVD reactor, depositing silicon onto said substrate to form an a-Si layer;
introducing said substrate into said first PECVD reactor, said first PECVD reactor including an upper electrode and a lower electrode, the upper electrode having an outer surface made of a nucleating metal that is capable of inducing nucleation sites in a-Si;
generating a plasma between said upper electrode and said lower electrode, thereby causing said nucleating metal to deposit onto said a-Si layer; and
annealing the α-Si layer on said substrate, thereby forming said poly-Si layer on said substrate.

36. The method of claim 35 wherein said metal is iron, cobalt, rubidium, palladium, osmium, iridium, platinum, scandium, titanium, vanadium, chromium, manganese, copper, zinc, gold, silver or a combination or an alloy thereof.

37. The method of claim 35 wherein said metal is nickel, chromium, platinum, or palladium.

38. The method of claim 35 wherein said metal is nickel or palladium.

39. The method of claim 35 wherein said substrate is glass or quartz and said generating step results in the deposition of a layer of said metal onto said a-Si layer that is less than 10 angstroms thick.

40. The method of claim 35 wherein said substrate is glass or quartz and said generating step results in the deposition of isolated islands of said metal onto said a-Si layer.

41. The method of claim 35 wherein said upper electrode is a gas inlet manifold and said lower electrode is a substrate electrode.

42. The method of claim 35 wherein said substrate is an insulative substrate.

43. The method of claim 35 wherein said substrate is glass or quartz.
